(19) United States
(12) Patent Application Publication
(10) Pub. No.: US 2006/0228862 A1
(43) Pub. Date: Oct. 12, 2006

(54) FET DESIGN WITH LONG GATE AND DENSE PITCH

(75) Inventors: Brent A. Anderson, Jericho, VT (US); Edward J. Nowak, Essex Junction, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 10/907,568

(22) Filed: Apr. 6, 2005

(51) Int. Cl. H01L 21/00

(52) U.S. Cl. 438/279

(57) ABSTRACT

A complementary metal oxide semiconductor field effect transistor (CMOS FET) design layout and method of fabrication are disclosed that provide a long gate and dense pitch in which gate contacts are positioned directly on top of the gates, and source and drain contacts are made into contact CA bars with contact pads outside the RX (active silicon conductor) region of the FET.

### FIELD OF THE INVENTION

The present invention relates generally to a field effect transistor (FET) design with a long gate and dense pitch, and more particularly pertains to a complementary metal oxide semiconductor field effect transistor (CMOS FET) design layout and method of fabrication that provides a long gate and dense pitch in which gate contacts are positioned directly on top of the gates, and source and drain contacts are made into contact CA bars with contact pads outside the RX (active silicon conductor) region of the FET.

### BACKGROUND OF THE INVENTION

In the present state of the art of CMOS FETs, device scaling issues are driving future generations of device designs to slow gate length scaling to minimize device leakage. This requires modifications to CMOS FET design layouts to allow for contacts to the source and drain regions without increasing the device minimum pitch, which corresponds to the length of one CMOS FET device from the source through the gate to the drain.

FIG. 1 illustrates a standard prior art CMOS FET device design layout wherein the length of the polySi gate, shown as Lpoly, is less than one third the pitch of the prior art CMOS FET device, which corresponds to the length of one CMOS FET device from the source through the gate to the drain. FIG. 8 illustrates the pitch of a CMOS FET device, shown as extending between two regular and well-defined features of adjacent CMOS FET devices. In the prior art CMOS FET device design layout, the RX (active silicon conductor) contacts 10 to the source and drain regions are in-line, and the gate contacts 12 and contact pads 14 are external to the RX region.

FIG. 1 illustrates a top planar view of a standard prior art CMOS FET device design layout of four CMOS FET devices having alternate source regions S and drain regions D separated by gates G, wherein each CMOS FET device is formed by a sequential source region S, gate G and drain region D. In a typical circuit layout, the source region S for one CMOS FET device forms the drain region D for an adjacent CMOS FET device, such that each region is labeled S/D. FIG. 1 is only an illustrative layout of four CMOS FET devices, and a typical prior art integrated circuit IC design would include a much larger number of CMOS FET devices.

In the standard prior art CMOS FET device design layout, the length of the polySi gate, Lpoly, is less than one third the pitch of the prior art CMOS FET device which corresponds to the length of one CMOS FET device from the source through the gate to the drain as explained above. In the prior art CMOS FET device design layout, the RX (active silicon conductor) contacts 10 to the source/drain regions S/D are in-line, and are to the tops of the source/drain regions S/D. The gate contacts 12 are to the sides of the gates, and the gate contacts 12 and gate contact pads 14 are positioned alternately on opposite sides of the CMOS FET devices, and are external to the RX region.

### SUMMARY OF THE INVENTION

Accordingly, it is a primary object of the present invention to provide an FET layout design and method of fabrication that provide an FET with a long gate and a dense pitch.

The present invention provides a modified layout of a traditional FET to support long gate lengths while not increasing and adversely impacting upon the device minimum pitch, which would reduce the device density. Pursuant to the present invention, gate contacts are positioned directly on top of the gates, and source and drain contacts are made into contact CA bars with pads outside the active silicon conductor (RX) region. A mask may be added to the fabrication process to open spacers on top of the gates for the gate contacts and between the gates for the contact CA bars while preventing shorts between the source/drain and the gate.

### BRIEF DESCRIPTION OF THE DRAWINGS

The foregoing objects and advantages of the present invention for an FET design with long gate and dense pitch may be more readily understood by one skilled in the art with reference being had to the following detailed description of several embodiments thereof, taken in conjunction with the accompanying drawings wherein like elements are designated by identical reference numerals throughout the several views, and in which:

FIG. 1 is top planar view of a standard prior art CMOS FET device design layout wherein the length of the polySi gate is less than one third the pitch of the prior art CMOS FET device.

FIG. 2 is a top planar view of a CMOS FET device design layout pursuant to the present invention having a long gate with dense pitch layout wherein the length of the polySi gate Lpoly is greater than one third the pitch of the CMOS FET device.

FIG. 3 illustrates a side elevational view of one embodiment of a CMOS FET device design layout pursuant to the present invention having a long gate with dense pitch layout.

FIG. 4 is a top planar view of an embodiment of a CMOS FET device design layout pursuant to the present invention wherein the contacts to the source regions S and drain regions D extend to contact pads that are in-line on one side of the CMOS FET devices, and also illustrates the formation of open spacers on top of the gates and between the gates.

FIG. 5 illustrates a top planar view of one embodiment of the present invention in a FINFET design.

FIGS. 6 through 8 illustrate the sequential process steps of fabrication of an additional embodiment of the present invention for an FET design layout having a long gate with dense pitch.

FIG. 9 illustrates the structure of a typical CMOS FET device, and is referred to in a more detailed explanation of a typical fabrication process.

### DETAILED DESCRIPTION OF THE INVENTION

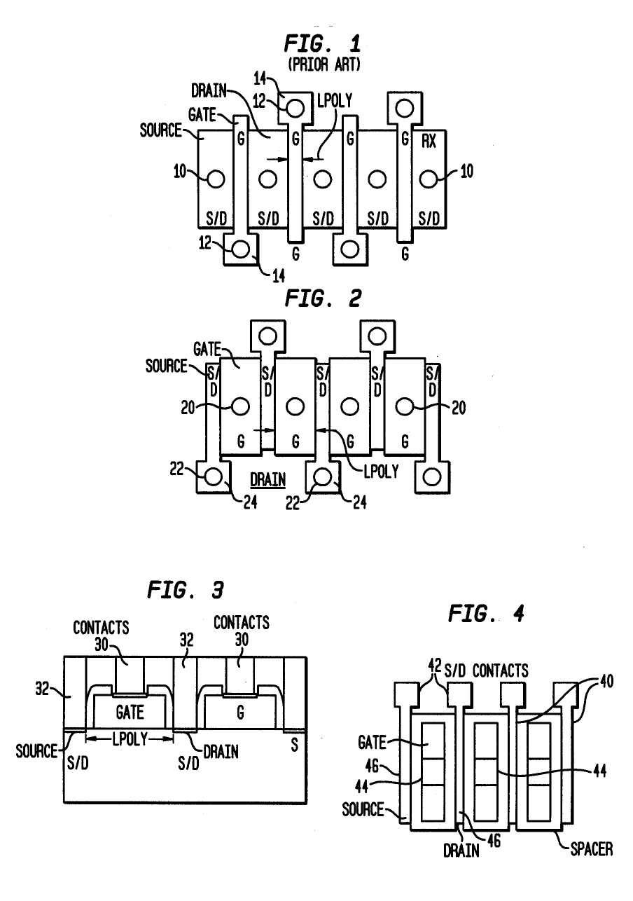

FIG. 2 illustrates a CMOS FET device design layout pursuant to the present invention having a long gate with dense pitch layout wherein the length of the polySi gate Lpoly is greater than one third the pitch of the CMOS FET device, which corresponds to the length of one CMOS FET device from the source through the gate to the drain.

FIG. 2 illustrates a top planar view of a CMOS FET device design layout pursuant to the present invention of four CMOS FET devices having alternate source/drain regions S/D separated by gates G, wherein each CMOS FET device is formed by a sequential source region S, gate G and drain region D. FIG. 2 is only an illustrative layout of four CMOS FET devices, and a typical integrated circuit IC design layout would include a much larger number of CMOS FET devices.

In the CMOS FET device design layout of the present invention illustrated in FIG. 2, the gate contacts 20 to the gates are in-line, and are to the tops of the gates G. The source/drain S/D contacts 22 are to the sides of the sources and drains external to the RX region, and the S/D contacts 22 and contact pads 24 are positioned alternately on opposite sides of the CMOS FET devices.

In alternative embodiments of the CMOS FET device design layout pursuant to the present invention, as in the embodiment of FIG. 4, the contacts to the source/drain regions S/D can be in-line on one side of the CMOS FET devices.

The FET device design and layout of the present invention provides longer gates without having to increase the pitch of the FET device, and the longer gates provide improved device leakage.

FIG. 3 illustrates a side elevational view of one embodiment of a CMOS FET device design layout pursuant to the present invention having a long gate with dense pitch layout, and wherein the length of the polySi gate Lpoly is greater than one third the pitch of the CMOS FET device. FIG. 3 illustrates two CMOS FET devices having alternate source/drain regions S/D separated by gates G, wherein each CMOS FET device is formed by a sequential source region S, gate G and drain region D, with the realization that a typical integrated circuit IC design layout would include a much larger number of CMOS FET devices.

In the CMOS FET device design layout of the present invention illustrated in FIG. 3, the gate contacts 30 to the gates G are in-line, and are made to the tops of the gates G. The source/drain S/D contacts are provided by long CA bars 32 that strap across the tops of the S/D regions between the gates G to provide lower resistance contacts to the S/D regions, and the CA bars extend to S/D contact pads external to the RX region, positioned alternately on opposite sides of the CMOS FET devices as shown in FIG. 2, or in-line on one side of the CMOS FET devices as shown in FIG. 4.

FIG. 4 illustrates an embodiment of a CMOS FET device design layout pursuant to the present invention wherein the contacts/CA bars 40 extend across the tops of the source/drain regions S/D and extend to contact pads 42 that are in-line on one side of the CMOS FET devices.

FIG. 4 also illustrates that spacers 44 are opened on top of the gates G to provide for the contact bars extending to the tops of the gates G, and spacers 46 are opened between the gates to provide for the contact bars 40 extending across the tops of the source/drain regions S/D. The embodiment of FIG. 4 forms the structure of the gates G prior to fabrication of the contact bars extending to the tops of the gates G and the contact bars 40 extending across the tops of the source/drain regions S/D. A mask may be added to the fabrication process to open the spacers 44, 46 without providing shorts between the source/drain and the gate.

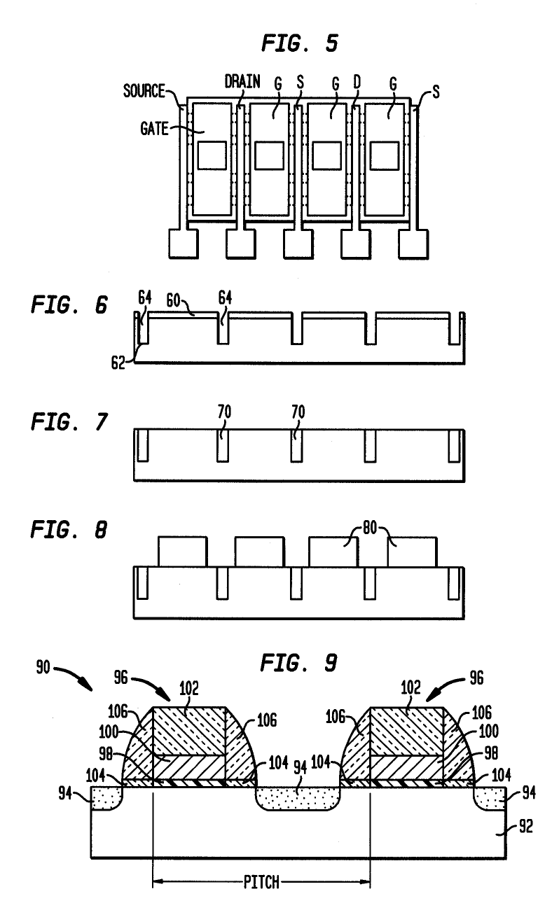

FIG. 5 illustrates a top planar view of one embodiment of the present invention in a FINFET design. A FINFET comprises a double-gated MOSFET that includes a very thin vertical Si layer (Fin) for the channel, with two gates, one on each side of the channel. The term “Fin” denotes a semiconductor material that is employed as the body of the FET. The two gates are electrically connected so that they serve to modulate the channel. Short-channel effects are greatly suppressed in such a structure because the two gates very effectively terminate the drain field line preventing the drain potential from being felt at the source end of the channel. Consequently, the variation of the threshold voltage with drain voltage and with gate length of a prior art double-gated MOSFET is much smaller than that of a conventional single-gated structure of the same channel length.

For FinFET applications, it is beneficial to provide a structure that has the thinnest single crystal silicon Fin possible for the device body. However, this makes contacting of the source and drain regions quite difficult. Optimally, the device portion of the Fin is quite thin, with the source and drain regions being thicker, in order to facilitate silicide growth and metal contact schemes.

The present invention incorporates the following changes in a device design, versus a prior art device design:

The gate contacts of the present invention are made to the tops of the gates, versus on the sides of the gates as in the prior art design of FIG. 1.

The source and drain contacts are made on the side of an RX (active silicon conductor) island.

Long contact CA bars strap across the source and drain regions to lower resistance.

An extra mask may be used in the fabrication process to open spacers on the tops of the gates and also between the gates.

FIGS. 6 through 8 illustrate the sequential process steps of fabrication of an additional embodiment of the present invention for an FET design layout having a long gate with dense pitch wherein the CA contact bars for the contacts to the S/D regions are formed prior to formation of the gate structures. FIG. 6 illustrates a first process step of etching through a nitride cap 60 on top of a silicon substrate 62 and into the silicon substrate to form channels 64 between future FET devices. FIG. 7 illustrates a subsequent process step wherein the channels between the future FET devices are filled with W (tungsten) silicide 70 to form the CA contact bars for the contacts to the S/D regions, and the structure is then subjected to CMP (chemical mechanical polishing) to remove the nitride cap 60. FIG. 8 also illustrates the pitch of a CMOS FET device, shown as extending between two regular and well-defined features, the left edges of the gates, of adjacent CMOS FET devices.

FIG. 9 is a schematic illustration of the formation of exemplary gates 80 for the FET devices with standard processing as described herein below.

FIG. 9 illustrates the structure of a typical CMOS FET device, and is referred to in the following more detailed explanation of a typical fabrication process. The IC structure 90 includes a semiconductor substrate 92, source/drain regions 94 located within the semiconductor substrate, and gate structures 96 that are located on the surface of the semiconductor substrate 92. Each gate structure 96 includes a gate dielectric 98, a conductor 100, a dielectric cap 102, a dielectric liner 104, and spacers 106.

The semiconductor substrate 92 of structure 10 can comprise any semiconducting material including, but not limited to: Si, Ge, SiGe, SiC, SiGeC, GaAs, InAs, InP and all other III/V compound semiconductors. Semiconductor substrate 92 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 92 be composed of a Si-containing semiconductor material, i.e., a semiconductor material that includes silicon. The semiconductor substrate 92 may be doped, undoped or contain doped and undoped regions therein.

The semiconductor substrate 92 may also include a first doped (n- or p-) region, and a second doped (n- or p-) region. These doped regions are known as “wells”. The first doped region and the second doped region may be the same, or they may have different conductivities and/or doping concentrations.

Trench isolation regions between the individual devices are typically already formed in the semiconductor substrate at this point of the present invention utilizing conventional processes well known to those skilled in the art.

A gate dielectric 98 is formed on the entire surface of the structure 90 including the semiconductor substrate 92 and atop the isolation region, if it is present and if it is a deposited dielectric. The gate dielectric 98 can be formed by a thermal growing process such as, for example, oxidation, nitridation or oxynitridation. Alternatively, the gate dielectric 98 can be formed by a deposition process such as, for example, chemical vapor deposition (CVD), plasma-assisted CVD, atomic layer deposition (ALD), evaporation, reactive sputtering, chemical solution deposition and other like deposition processes. The gate dielectric 98 may also be formed utilizing any combination of the above processes.

The gate dielectric 98 is comprised of an insulating material including, but not limited to: an oxide, nitride, oxynitride and/or silicate including metal silicates and nitrided metal silicates. In one embodiment, it is preferred that the gate dielectric 98 is comprised of an oxide such as, for example, SiO₂, HfO₂, ZrO₂, Al₂O₃, TiO₂, La₂O₃, SrTiO₃, LaAlO₃, and mixtures thereof.

The physical thickness of the gate dielectric 98 may vary, but typically, the gate dielectric 98 has a thickness from about 0.5 to about 10 nm, with a thickness from about 1 to about 3 nm being more typical.

After forming the gate dielectric 98, a blanket layer of polysilicon (i.e., polySi) which becomes the polySi gate conductor 100 shown in FIG. 9 is formed on the gate dielectric 98 utilizing a known deposition process such as, for example, physical vapor deposition, CVD or evaporation. The blanket layer of polysilicon may be doped or undoped. If doped, an in-situ doping deposition process may be employed in forming the same. Alternatively, a doped polySi layer can be formed by deposition, ion implantation and annealing. The doping of the polySi layer will shift the workfunction of the silicided metal gate formed. Illustrative examples of dopant ions include As, P, B, Sb, In, Al, Ga, or mixtures thereof. Typical doses for the ion implants are 1E14(=1×10¹⁴) to 1E16(=1×10¹⁶) atoms/cm² or more typically 1E15 to 5E15 atoms/cm². The thickness, i.e., height, of the polysilicon layer deposited at this point of the present invention may vary depending on the deposition process employed. Typically, the polysilicon layer has a vertical thickness from about 20 to about 180 nm, with a thickness from about 40 to about 150 nm being more typical.

After deposition of the blanket layer of polysilicon, a dielectric cap 102 is formed atop the blanket layer of polysilicon gate conductor utilizing a deposition process such as, for example, physical vapor deposition or chemical vapor deposition. The dielectric cap 102 may be an oxide, nitride, oxynitride or any combination thereof. The dielectric cap 102 can be comprised of a different dielectric material than spacer 106 to be defined in detail herein below. In one embodiment, a nitride such as, for example, Si₃N₄, is employed as the dielectric cap 102. In yet another embodiment, which is preferred, the dielectric cap 102 is an oxide such as SiO₂. The thickness, i.e., height, of the dielectric cap 102 is from about 10 to about 300 nm, with a thickness from about 30 to about 140 nm being more typical.

The blanket polysilicon layer and dielectric cap layer are then patterned by lithography and etching so as to provide patterned gate stacks 96. The patterned gate stacks may have the same dimension, i.e., length, or they can have variable dimensions to improve device performance. Each patterned gate stack at this point of the present invention includes a polySi gate conductor 100 and a dielectric cap 102. The lithography step includes applying a photoresist to the upper surface of the dielectric cap layer, exposing the photoresist to a desired pattern of radiation and developing the exposed photoresist utilizing a conventional resist developer. The pattern in the photoresist is then transferred to the dielectric cap layer and the blanket layer of polysilicon utilizing one or more dry etching steps. In some embodiments, the patterned photoresist may be removed after the pattern has been transferred into the dielectric cap layer. In other embodiments, the patterned photoresist is removed after etching has been completed.

Suitable dry etching processes that can be used in the present invention in forming the patterned gate stacks include, but are not limited to: reactive ion etching, ion beam etching, plasma etching or laser ablation. The dry etching process employed is typically selective to the underlying gate dielectric 98 therefore this etching step does not typically remove the gate dielectric. In some embodiments, this etching step may however be used to remove portions of the gate dielectric 98 that are not protected by the gate stacks. A wet etching process can also be used to remove portions of the gate dielectric 98 that are not protected by the gate stacks.

Next, a dielectric liner 104 is formed on all exposed surfaces containing silicon including at least the polysilicon gate conductor 100. The dielectric liner 104 can also extend onto horizontal surfaces of the semiconductor substrate 92. The dielectric liner 104 may comprise any dielectric material that contains an oxide, nitride, oxynitride or any combination thereof. The dielectric liner 104 is formed via a thermal growing process such as oxidation, nitridation or oxynitridation. The dielectric liner 104 is a thin layer whose thickness is typically from about 1 to about 50 nm.

At least one spacer 106 is formed on exposed sidewalls of each patterned gate stack as well as atop the dielectric liner. The at least one spacer 106 is comprised of an insulator such as an oxide, nitride, oxynitride and/or any combination thereof and it typically is composed of a different material than the dielectric liner 104 and the dielectric cap 102. Preferably, nitride spacers are formed. The at least one spacer 106 is formed by deposition and etching. Note that the etching step used in forming the spacers 106 also can remove dielectric liner 104 from atop the substrate such that a portion of the semiconductor substrate 92 is exposed.

The width of the spacer 106 must be sufficiently wide such that the source and drain silicide contacts (to be subsequently formed) do not encroach underneath the edges of the gate stack. Typically, the source/drain silicide does not encroach underneath the edges of the gate stack when the spacer has a width, as measured at the bottom, from about 5 to about 80 nm.

After spacer formation, source/drain diffusion regions 94 are formed into the substrate 92 at the exposed portions. The source/drain diffusion regions 94 are formed utilizing ion implantation and an annealing step. The annealing step serves to activate the dopants that were implanted by the previous implant step. The conditions for the ion implantation and annealing are well known to those skilled in the art.

Next, a material stack comprising a conformal dielectric layer and a planarizing dielectric (not shown) are formed over the entire structure shown in FIG. 9. The conformal dielectric layer is formed first followed by the planarizing dielectric layer. The conformal dielectric layer comprises any dielectric material including an oxide, nitride, and/or oxynitride. Specifically, the conformal dielectric layer comprises a nitride such as Si₃N₄. The conformal dielectric layer, which is formed utilizing a conventional deposition process, has a thickness after deposition from about 15 to about 200 nm.

After forming the conformal dielectric layer over the structure shown in FIG. 9, a planarizing dielectric layer (not shown) can be formed. The planarizing dielectric layer comprises an oxide such as a high density oxide or an oxide deposited from TEOS. Alternatively, the planarizing dielectric layer may comprise a doped silicate glass, such as boron doped silicate glass (BSG) or phosphorus doped silicate glass (PSG), a spin-coatable polymeric material such as hydrogen silsesquioxane (HSQ), or a photoresist. The planarizing dielectric layer is formed by conventional techniques well known to those skilled in the art. The thickness of the planarizing dielectric layer formed at this point may vary depending on the type of material employed. Typically, the planarizing dielectric layer has a thickness from about 50 to about 800 nm.

While several embodiments and variations of the present invention for FET design with long gate and dense pitch are described in detail herein, it should be apparent that the disclosure and teachings of the present invention will suggest many alternative designs to those skilled in the art.

What is claimed is:

1. A field effect transistor (FET) having a long gate and dense pitch, comprising:
the FET including a gate separating a source region from a drain region;
a gate contact positioned directly on top of and extending down to the gate;
a source contact comprising a contact bar extending across the source region and extending to a source contact pad outside an RX (active silicon conductor) region of the FET;
a drain contact comprising a contact bar extending across the drain region and extending to a drain contact pad outside the RX (active silicon conductor) region.

2. The FET of claim 1, wherein the length of the gate, extending between the source region and the drain region, is more than one third the pitch of the FET, which corresponds to the length of the FET from the source region through the gate to the drain region.

3. The FET of claim 2, wherein the contact to the source region and the contact to the drain region extend to respective source and drain contact pads that are in-line on one side of the FET.

4. The FET of claim 2, wherein the source contact pad and the drain contact pad are positioned on opposite sides of the FET.

5. The FET of claim 2, comprising a double-gated FET that includes a very thin vertical layer defining an FET channel, with two gates, one gate on each side of the FET channel.

6. The FET of claim 2, comprising a complementary metal oxide semiconductor field effect transistor (CMOS FET).

7. The FET of claim 1, wherein the contact to the source region and the contact to the drain region extend to respective source and drain contact pads that are in-line on one side of the FET.

8. The FET of claim 1, wherein the source contact pad and the drain contact pad are positioned on opposite sides of the FET.

9. The FET of claim 1, comprising a double-gated FET that includes a very thin vertical layer defining an FET channel, with two gates, one gate on each side of the FET channel.

10. The FET of claim 1, comprising a complementary metal oxide semiconductor field effect transistor (CMOS FET).

11. An integrated circuit comprising a plurality of adjacent FETs as specified by claim 1, wherein each FET device is formed by a sequential source region, gate and drain region, and in the integrated circuit layout, the source region for one FET device forms the drain region for an adjacent FET device, such that each region forms a source/drain region.

12. A method of fabricating a field effect transistor (FET) having a long gate and dense pitch, comprising:
fabricating the FET in an integrated circuit (IC) with a gate separating a source region from a drain region;
forming a gate contact in the IC directly on top of and extending down to the gate;
forming a source contact as a contact bar extending across the source region and extending to a source contact pad outside an RX (active silicon conductor) region of the FET;
forming a drain contact as a contact bar extending across the drain region and extending to a drain contact pad outside the RX (active silicon conductor) region.

13. The method of claim 12, including forming the structure of the gate prior to forming the gate contact and the contact bars extending across the source region and the drain region, wherein a mask is used in the fabricating method to open a spacer on top of the gate to provide for a contact extending to the top of the gate, and open spacers on opposite sides of the gate to provide for the contact bars extending across the source region and the drain region.

14. The method of claim 12, wherein the contact bar for the contact to the source region and the contact bar for the contact to the drain region are formed prior to formation of the structure of the gate, comprising:
etching through a nitride cap on top of a silicon substrate and into the silicon substrate to form channels between FETs;
filling the channels between the FETs with W (tungsten) silicide to form the contact bars for the source and drain regions;
using chemical mechanical polishing to remove the nitride cap.

15. The method of claim 12, including fabricating the FET such that the length of the gate, extending between the source region and the drain region, is more than one third the pitch of the FET, which corresponds to the length of the FET from the source region through the gate to the drain region.

16. The method of claim 12, including fabricating the FET such that the contact to the source region and the contact to the drain region extend to respective source and drain contact pads that are in-line on one side of the FET.

17. The method of claim 12, including fabricating the FET such that the source contact pad and the drain contact pad are positioned on opposite sides of the FET.

18. The method of claim 12, including fabricating a double-gated FET that includes a very thin vertical layer defining an FET channel, with two gates, one gate on each side of the FET channel.

19. The method of claim 12, including fabricating a complementary metal oxide semiconductor field effect transistor (CMOS FET).

20. The method of claim 12, for an integrated circuit comprising a plurality of adjacent FETs, wherein each FET device is formed by a sequential source region, gate and drain region, and in the integrated circuit layout, the source region for one FET device forms the drain region for an adjacent FET device, such that each region forms a source/drain region.
